(19) United States
(12) Patent Application Publication
(10) Pub. No.: US 2026/0372212 A1
(43) Pub. Date: Nov. 19, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Min-Shiang Hsu, Kaohsiung City (TW); Yu-Ping Wang, Hsinchu City (TW); Chi-Horn Pai, Tainan City (TW)

(73) Assignee: UNITED MICROELECTRONICS CORP., Hsin-Chu City (TW)

(21) Appl. No.: 19/237,016

(22) Filed: Jun. 13, 2025

(30) Foreign Application Priority Data
May 14, 2025 (TW) 114118033

(51) Int. Cl. H10W 90/00; H10W 44/00; H10W 70/00; H10W 70/05; H10W 70/63

(52) U.S. Cl. CPC H10W 90/401; H10W 44/601; H10W 70/095; H10W 70/099; H10W 70/635; H10W 90/701; H10W 90/724

(57) ABSTRACT

A method for fabricating a semiconductor device includes the steps of providing a first interposer having a first passive device therein, providing a second interposer having a second passive device therein, bonding the first interposer and the second interposer to form a stack structure, bonding dies having different functionalities on the second interposer, and forming micro bumps between the dies and the second interposer. Preferably, each of the first passive device and the second passive device includes a deep trench capacitor.

### BACKGROUND OF THE INVENTION

### 1. FIELD OF THE INVENTION

The present invention relates to a method for fabricating semiconductor devices, and more particularly, to an advanced chip packaging integration technique.

### 2. DESCRIPTION OF THE PRIOR ART

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating a semiconductor device includes the steps of providing a first interposer having a first passive device therein, providing a second interposer having a second passive device therein, bonding the first interposer and the second interposer to form a stack structure, bonding dies having different functionalities on the second interposer, and forming micro bumps between the dies and the second interposer. Preferably, each of the first passive device and the second passive device includes a deep trench capacitor.

According to another aspect of the present invention, a semiconductor device includes a stack structure having a first interposer having a first passive device therein, a second interposer bonded to the first interposer, and hybrid bonds connecting the first interposer and the second interposer. Preferably, the second interposer includes a second passive device therein.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a structural view of a semiconductor device according to an embodiment of the present invention.

FIG. 2 illustrates a structural view of a semiconductor device according to an embodiment of the present invention.

FIG. 3 illustrates a structural view of a semiconductor device according to an embodiment of the present invention.

FIG. 4 illustrates a structural view of a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIG. 1, FIG. 1 is a schematic cross-sectional view illustrating the structure of a semiconductor device according to one embodiment of the present invention. As shown in FIG. 1, a first interposer 12 composed of a semiconductor material is initially provided. The first interposer 12 includes a substrate 14, which may be, for example, a silicon substrate, an epitaxial silicon substrate, a silicon carbide substrate, or a silicon-on-insulator (SOI) substrate. These examples are provided by way of illustration and not limitation, and any suitable semiconductor substrate falls within the scope of the present invention. In the present embodiment, the first interposer 12 preferably includes a plurality of passive components, such as a plurality of deep trench capacitors (DTCs) 16. These passive components may be fabricated using process nodes such as 65 nm or 130 nm technology, depending on design requirements.

According to one embodiment of the present invention, the first interposer 12 may include an interlayer dielectric (ILD) or inter-metal dielectric (IMD) layer 18 disposed over the substrate 14 and a plurality of metal interconnections 20 embedded within the IMD layer 18. The topmost metal interconnections 20 may serve as hybrid bond pads 24 or direct bond interconnects (DBIs), which can be aligned and bonded to another interposer or wafer in a subsequent hybrid bonding process. In addition, the substrate 14 of the first interposer 12 preferably includes one or more through-silicon vias (TSVs) 26 for electrically connecting the passive components formed over the substrate 14, and these TSVs may be subsequently used to connect to solder bumps or other packaging structures. In the present embodiment, the ILD and IMD layers 18 may include oxide materials such as but not limited to tetraethyl orthosilicate (TEOS)-based oxides. The metal interconnections 20, hybrid bonds 24, and TSVs 26 may include metals such as aluminum (Al), chromium (Cr), copper (Cu), tantalum (Ta), molybdenum (Mo), tungsten (W), or combinations thereof, without being limited thereto.

Next, a second interposer 22 composed of a semiconductor material is provided. Similar to the first interposer 12, the second interposer 22 preferably includes a wafer or substrate 14 formed of a semiconductor material. The substrate 14 may be, for example, a silicon substrate, an epitaxial silicon substrate, a silicon carbide substrate, or a silicon-on-insulator (SOI) substrate, all of which are within the scope of the present invention. In addition, the second interposer 22 of the present embodiment also includes a plurality of passive components, such as a plurality of deep trench capacitors (DTCs) 16. These passive components may likewise be fabricated using 65 nm, 130 nm, or comparable process nodes, depending on the application requirements.

Similar to the configuration of the first interposer 12, the second interposer 22 may include one or more interlayer dielectric (ILD) or inter-metal dielectric (IMD) layers 18 disposed over the substrate 14, and a plurality of metal interconnections 20 embedded within the IMD layer 18. The topmost metal interconnections 20 may function as hybrid bond pads 24 or direct bond interconnects (DBIs), which can be bonded to another interposer such as the hybrid bond pads 24 of the first interposer 12 during a subsequent fabrication process. Additionally, the substrate 14 of the second interposer 22 preferably includes one or more TSVs 36 configured to electrically connect to the passive components formed on the substrate 14. These TSVs 36 may also be used in a subsequent process for connection to solder bumps or other external I/O structures. In the present embodiment, the ILD and IMD layers 18 may include oxide-based dielectric materials such as, but not limited to, tetraethyl orthosilicate (TEOS). The metal interconnections 20, hybrid bond pads 24, and TSVs 36 may be formed using aluminum (Al), chromium (Cr), copper (Cu), tantalum (Ta), molybdenum (Mo), tungsten (W), or combinations thereof, though the invention is not limited thereto.

It is noteworthy that, in the present embodiment, the TSVs 26 formed in the substrate 14 of the first interposer 12 and the TSVs 36 formed in the substrate 14 of the second interposer 22 are preferably fabricated using a via-middle process. For example, the present embodiment may first perform a front-end-of-line (FEOL) process to form the deep trench capacitors (DTCs) 16 within the substrate 14. Subsequently, the via-middle process is employed to form the TSVs 26 and 36 within the substrate 14. Thereafter, a back-end-of-line (BEOL) process is performed to form the inter-metal dielectric (IMD) layers 18 and metal interconnects 20 over the substrate 14. Since the TSVs 26 and 36 are formed using a via-middle process, they are confined within the substrate 14 and do not extend into the IMD layer 18.

Subsequently, a contact pad process may be performed to form a dielectric layer 40 on the backside of the substrate 14 of the second interposer 22. A redistribution layer (RDL) 42 is then formed within the dielectric layer 40, and one or more bonding pads 48 are formed to connect to the RDL 42 and are exposed on the surface of the dielectric layer 40. In the present embodiment, the dielectric layer 40 may include an organic material layer based on polyimide. The redistribution layer 42 and bonding pads 48 may include aluminum (Al), copper (Cu), silver (Ag), gold (Au), nickel (Ni), tungsten (W), or alloys thereof, without limitation.

It should be noted that, in the present embodiment, both the first interposer 12 and the second interposer 22 are passive component interposers. In other words, aside from passive components, the first interposer 12 and the second interposer 22 preferably do not include other components such as active devices. A hybrid bonding process is then performed to bond the first interposer 12 and the second interposer 22 together, thereby forming a stacked structure 38. During the bonding process, the second interposer 22 may first be flipped such that the front side of the second interposer 22, namely the side exposing the metal interconnections 20 faces the front side of the first interposer 12, which also exposes its metal interconnections 20. The two interposers are then aligned and brought into direct contact and bonded using for example a thermal process. As a result, direct bond interconnects (DBIs) or hybrid bonds 24 are formed through direct metal-to-metal connection.

A plurality of bumps 44 or solder balls may then be formed to connect to the TSVs 26 at the bottom side of the first interposer 12. Thereafter, a plurality of dies 28 and 30 having different functionalities, which have undergone wafer dicing processes, may be mounted onto the backside of the second interposer 22. The dies 28 and 30 may be connected to the bonding pads 48 on the backside of the second interposer 22 by means of micro-bumps 46 or hybrid bonding, depending on the specific product requirements or specifications. In the present embodiment, the bumps 44 and micro-bumps 46 may include aluminum (Al), copper (Cu), silver (Ag), gold (Au), nickel (Ni), tungsten (W), lead (Pb), tin (Sn), or alloys thereof, without limitation. Furthermore, the dies 28 and 30 may include, for example, high bandwidth memory (HBM) dies, radio frequency integrated circuit (RFIC) dies, power amplifier (PA) dies, or high electron mobility transistor (HEMT) dies based on group III-V semiconductors such as gallium nitride (GaN).

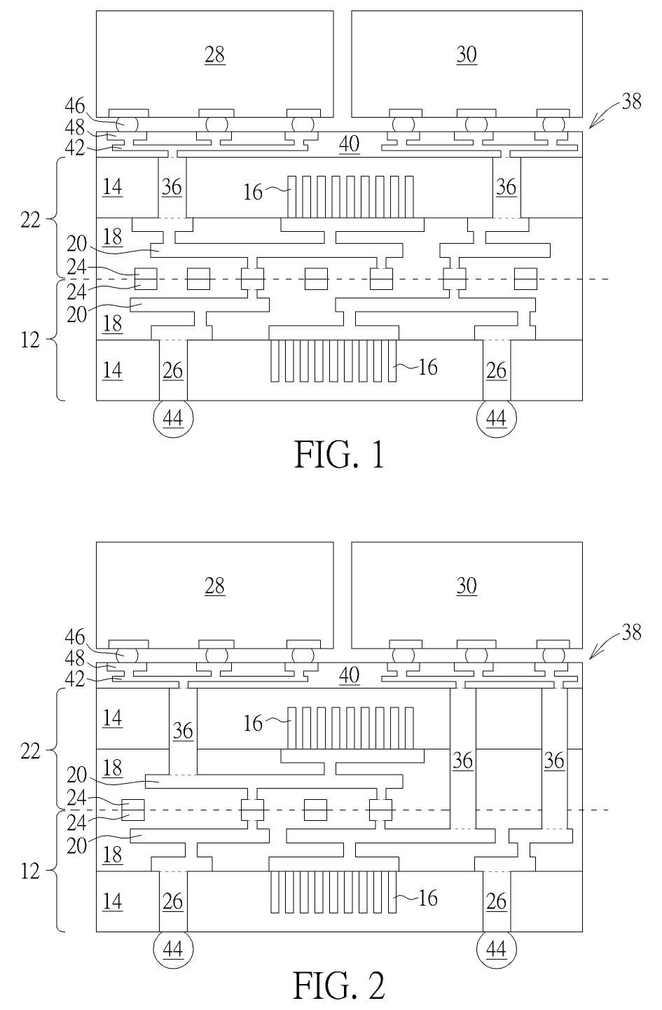

Referring to FIG. 2, FIG. 2 is a schematic cross-sectional view illustrating the structure of a semiconductor device according to another embodiment of the present invention. To maintain consistency with the previous embodiment, elements identical to those described in the preceding embodiment are preferably denoted with the same reference numerals. As shown in FIG. 2, unlike the previous embodiment in which the TSVs 26 in the substrate 14 of the first interposer 12 and the TSVs 36 in the substrate 14 of the second interposer 22 are both formed using a via-middle process, in the present embodiment, the TSVs 26 in the substrate 14 of the first interposer 12 are still formed using the via-middle process while the TSVs 36 in the substrate 14 of the second interposer 22 are formed using a via-last process.

In other words, as illustrated in FIG. 1, the present embodiment may first provide a first interposer 12 having pre-fabricated TSVs 26 and a second interposer 22 in which the back-end-of-line (BEOL) process has been completed but no TSVs are yet formed. A hybrid bonding process is then performed to bond the first interposer 12 and the second interposer 22 together, forming a stacked structure 38. Thereafter, the TSVs 36 are formed from the backside of the second interposer 22, followed by the bonding of multiple dies 28 and 30 having different functionalities onto the second interposer 22. Since the TSVs 36 are formed using a via-last process, they preferably extend through both the substrate 14 and the inter-metal dielectric (IMD) layer 18 of the second interposer 22, and may even extend into the IMD layer 18 of the first interposer 12. Similar to the embodiment shown in FIG. 1, the stacked structure 38 of the present embodiment is also formed by bonding the front side of the first interposer 12 to the front side of the second interposer 22.

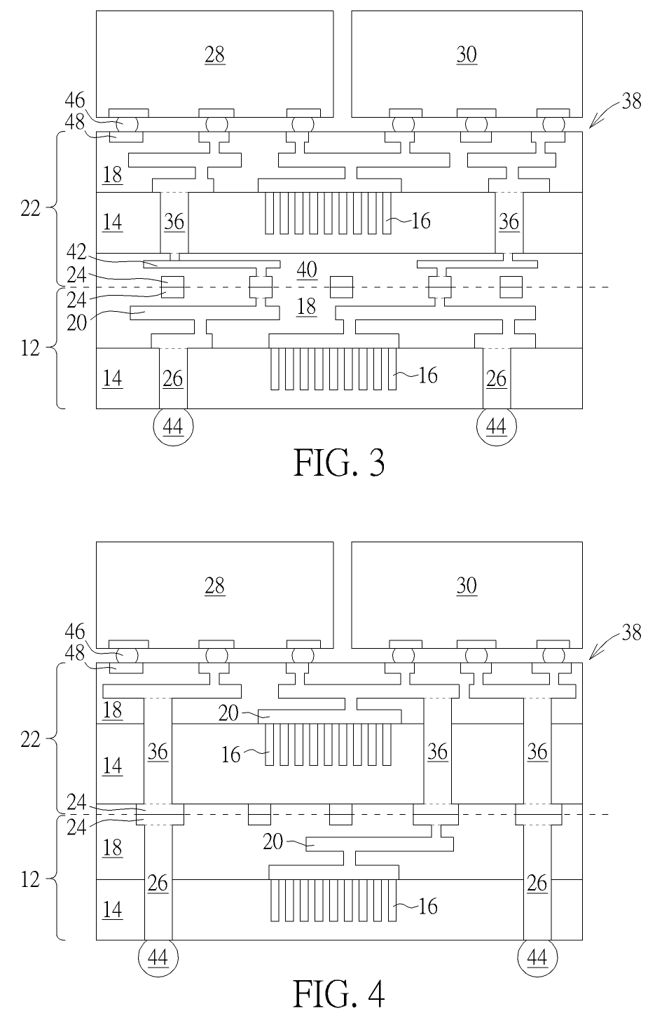

Referring to FIG. 3, FIG. 3 is a schematic cross-sectional view illustrating the structure of a semiconductor device according to yet another embodiment of the present invention. To maintain consistency with the preceding embodiments, elements identical to those previously described are preferably designated with the same reference numerals. As shown in FIG. 3, in the present embodiment, the TSVs 26 formed in the substrate 14 of the first interposer 12 and the TSVs 36 formed in the substrate 14 of the second interposer 22 are both formed using a via-middle process, similar to the embodiment illustrated in FIG. 1. In other words, the TSVs 26 and 36 are confined within the substrate 14 and do not extend into the inter-metal dielectric (IMD) layer 18.

In contrast to the embodiment shown in FIG. 1, in which the front side of the first interposer 12 is bonded to the front side of the second interposer 22 to form the stacked structure 38, the present embodiment preferably bonds the front side of the first interposer 12 to the backside of the second interposer 22 to form the stacked structure 38. For example, according to the process flow similar to that of FIG. 1, the present embodiment may first provide a first interposer 12 with pre-fabricated TSVs 26 and a second interposer 22 with TSVs 36 also formed therein. A dielectric layer 40 and a redistribution layer (RDL) 42 are then formed on the backside of the second interposer 22, i.e., the bottom surface of the substrate 14. Subsequently, a hybrid bonding process is performed to bond the metal interconnections 20 of the first interposer 12 to the bottom-side redistribution layer 42 of the second interposer 22 thereby forming hybrid bonds 24. Thereafter, a plurality of bumps 44 may be formed on the bottom side of the first interposer 12 and a plurality of dies 28 and 30 each having different functionalities and having undergone wafer dicing processes may be bonded to the front side of the second interposer 22 through micro-bumps 46.

Referring to FIG. 4, FIG. 4 is a schematic cross-sectional view illustrating the structure of a semiconductor device according to still another embodiment of the present invention. To maintain consistency with the preceding embodiments, elements identical to those described earlier are preferably designated with the same reference numerals. As shown in FIG. 4, similar to the embodiment in FIG. 3, the present embodiment forms the stacked structure 38 by bonding the front side of the first interposer 12 to the backside of the second interposer 22. However, unlike the embodiment in FIG. 3, in which the TSVs 26 and 36 formed in the substrates 14 of the first and second interposers 12 and 22, respectively, are fabricated using a via-middle process, the TSVs 26 and 36 in the present embodiment are both formed using a via-last process.

For example, according to the process flow similar to that of FIG. 1, the present embodiment may first provide a first interposer 12 and a second interposer 22, each having TSVs 26 and 36 formed therein by a via-last process. A hybrid bonding process is then performed to bond the front side of the first interposer 12 to the backside of the second interposer 22, such that the TSVs 26 of the first interposer 12 are aligned and bonded to the TSVs 36 of the second interposer 22 thereby forming a stacked structure 38.

Subsequently, a plurality of bumps 44 or solder balls may be formed to connect to the TSVs 26 located at the bottom or backside of the first interposer 12. A plurality of dies 28 and 30 each having different functionalities and having undergone wafer dicing processes may then be bonded to the front side of the second interposer 22. The dies 28 and 30 may be connected to the bonding pads 48 on the front side of the second interposer 22 by means of, for example, micro-bumps 46 or hybrid bonding, depending on the specific product design or specifications. Since both the TSVs 26 and 36 in the present embodiment are fabricated using a via-last process, the TSVs 26 and 36 preferably extend through at least the entire substrates 14 of both the first and second interposers 12 and 22 and further extend into the inter-metal dielectric (IMD) layers 18 to a certain depth. For example, the TSVs 26 in the first interposer 12 may extend through the entire substrate 14 and the entire IMD layer 18, whereas the TSVs 36 in the second interposer 22 may extend through the entire substrate 14 and partially into the IMD layer 18.

In summary, the present invention primarily discloses four types of packaging structures for stacking deep trench capacitor (DTC) interposers using hybrid bonding methods. In the embodiment of FIG. 1, the two interposers are preferably bonded front-to-front, combined with a via-middle process to form TSVs 26 and 36 within each interposer. The embodiment of FIG. 2 also employs front-to-front bonding of the two interposers, but utilizes a via-middle process for the TSVs 26 in one interposer and a via-last process for the TSVs 36 in the other interposer. The embodiment of FIG. 3 preferably bonds the two interposers front-to-back, using a via-middle process to form the TSVs 26 and 36 within each interposer. The embodiment of FIG. 4 bonds the two interposers front-to-back while employing a via-last process to form the TSVs 26 and 36 within each interposer.

Compared to conventional fabrication methods of deep trench capacitors which typically increase trench depth to enhance capacitance density, thereby leading to high aspect ratios and challenges in etching and deposition processes, the present invention employs the above four approaches to fabricate stacked packaging structures primarily based on deep trench capacitors. This significantly increases the capacitance density (greater than 3000 nF/mm²) of the deep trench capacitors and provides lower power consumption for applications such as high-performance computing (HPC) and artificial intelligence (AI).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a first interposer having a first passive device therein;
providing a second interposer having a second passive device therein; and
bonding the first interposer and the second interposer to form a stack structure.

2. The method of claim 1, further comprising bonding dies having different functionalities on the second interposer.

3. The method of claim 2, further comprising forming micro bumps between the dies and the second interposer.

4. The method of claim 1, wherein the first passive device comprise a deep trench capacitor.

5. The method of claim 1, wherein the first interposer comprises a first substrate and a first inter-metal dielectric (IMD) layer thereon and the second interposer comprises a second substrate and a second IMD layer thereon.

6. The method of claim 5, further comprising:
forming a first TSV in the first substrate; and
forming a second TSV in the second substrate and the second IMD layer.

7. The method of claim 5, further comprising:
forming a first TSV in the first substrate and the first IMD layer; and
forming a second TSV in the second substrate and the second IMD layer.

8. The method of claim 5, further comprising bonding a front side of the first interposer to a front side of the second interposer.

9. The method of claim 5, further comprising bonding a front side of the first interposer to a backside of the second interposer.

10. The method of claim 5, wherein the first substrate comprises a silicon wafer.

11. A semiconductor device, comprising:
a stack structure comprising:
a first interposer having a first passive device therein;
a second interposer bonded to the first interposer, wherein the second interposer comprises a second passive device therein; and
hybrid bonds connecting the first interposer and the second interposer.

12. The semiconductor device of claim 11, further comprising dies having different functionalities on the second interposer.

13. The semiconductor device of claim 11, further comprising micro bumps between the dies and the second interposer.

14. The semiconductor device of claim 11, wherein the first passive device comprise a deep trench capacitor.

15. The semiconductor device of claim 11, wherein the first interposer comprises a first substrate and a first inter-metal dielectric (IMD) layer thereon and the second interposer comprises a second substrate and a second IMD layer thereon.

16. The semiconductor device of claim 15, further comprising:
a first through-silicon via (TSV) in the first substrate; and
a second TSV in the second substrate.

17. The semiconductor device of claim 15, comprising:
a first TSV in the first substrate; and
a second TSV in the second substrate and the second IMD layer.

18. The semiconductor device of claim 15, comprising:
a first TSV in the first substrate and the first IMD layer; and
a second TSV in the second substrate and the second IMD layer.

19. The semiconductor device of claim 11, wherein a front side of the first interposer is facing a front side of the second interposer.

20. The semiconductor device of claim 11, wherein a front side of the first interposer is facing a backside of the second interposer.
